(19) United States
(12) Patent Application Publication
(10) Pub. No.: US 2002/0163004 A1
(43) Pub. Date: Nov. 7, 2002

(54) Packaged optical wavelength selector and optical gate for the same

(75) Inventors: Mike Liwak, Pickering (CA); Robert B. Thayer, Painted Post, NY (US); Tom Haslett, Toronto (CA); Dave Demmer, Toronto (CA)

Correspondence Address: HOFFMANN & BARON, LLP, 6900 JERICHO TURNPIKE, SYOSSET, NY, 11791, US

(73) Assignee: Photonami, Inc.

(21) Appl. No.: 10/071,477

(22) Filed: Feb. 7, 2002

(30) Foreign Application Priority Data
May 4, 2001 (CA) 2,346,518

(51) Int. Cl. H01L 27/15; H01L 21/00

(52) U.S. Cl. 257/79; 438/31

(57) ABSTRACT

A gate for an optical signal having a waveguide which can be coupled to a source of optical signals, where the waveguide comprises a cladding surrounding a core. A gate material is provided which is sized, shaped and positioned outside of the core such that an optical signal passing along the core interacts with said gate material. A source of power stimulates the gate material and the power source is switchable between on and off. The optical signal is attenuated by interacting with said gate material when the power is off and amplified by interacting with said gate material when the power is on. In one embodiment the gate is packaged into a planar light circuit having a multiplexer/demultiplexer at either end and a gate region including a plurality of gates. A method of forming such a device is also shown.

### FIELD OF THE INVENTION

This invention relates generally to the field of communications and more particularly to communication systems using optical signals. Most particularly, this invention relates to devices and methods for controlling optical signals for the purpose of switching the same in optical networks.

### BACKGROUND OF THE INVENTION

Advances in telecommunications equipment continue at a great rate. Optical signal communications and devices for controlling optical signals are becoming more common and more widespread. However, significant challenges remain before the full utilization of optical signals can be realized.

At present, optical systems are deployed with a capacity to transmit multiplexed signals down individual fibres. This is commonly known as dense wave division multiplexing or DWDM. Such multiplexing allows a single fibre to carry a multiplicity of simultaneous signals on individual signal bands or components. Currently, up to forty simultaneous signals can be sent down a single fibre and the commercial deployment of higher channel counts such as 160 signal component systems is imminent. When deployed this means that a single fibre optic cable is capable of acting like 160 virtual fibres. This is achieved by splitting the same band of the electromagnetic spectrum into smaller and smaller wavelength bands, each representing a single signal component.

The rapid addition of so much signal capacity to optical based communications systems puts pressure on the other parts of such systems to handle the increased signal load. Specifically, it becomes a significant problem to manage so much signal information particularly at the edge of such systems, or at any traffic intersection points in, for example, a network. The traditional way to manage these problems is to convert the optical signals into electrical signals to permit the signal components to be separately routed according to the end destination required. It is preferred to deal with such signals optically as long as possible to improve speed and capacity of the system, while at the same time maintaining costs of the equipment and components at a reasonable level.

One of the areas which has received considerable attention to date is the development of an optical gate for the purpose of allowing signals to be selected or deselected at will. Selection and deselection are important for the switching of signals in an optical form. Semiconductor optical amplifiers (SOAs) have been proposed in the literature [Simultaneous Wavelength Selector Using SOA-PLC Hybrid Wavelength Selector: Ito et al; ICEICE Trans. Electron., Vol E83-C, No. Jun. 6, 2000] in combination with an optical path. According to the reference, a planar waveguide can be provided with a demultiplexing device, and each demultiplexed signal component is then passed into an SOA. There, the signal may be amplified, and then passed out of the SOA onto a second planar waveguide which may include for example, a multiplexing device.

These types of devices have certain advantages. Specifically, the signal amplification occurs only in respect of a single signal component at a time, thereby eliminating any problems with cross talk. They also have fast response times and a good contrast ratio. However, such devices also have some severe limitations. Specifically, these devices can be very difficult to fabricate. The SOAs are made from a different material than the planar waveguide, and these different materials must be joined together. Bonding is required and the use of flip chip fabrication may be necessary to try to achieve the needed alignment between the elements. However, because only very small signal paths may be used, alignment problems can still be significant. These alignment issues can make fabrication expensive and unsuited to mass manufacturing. Further, the lattice structure of the SOA and the planar waveguides are different, meaning that certain processes, like annealing, can be very difficult due to differences in rates of thermal expansion between the materials, for example.

Even if aligned properly, there is a further problem of coupling the signals together. Typically a spot size converter is required into and out of the SOA, with attendant coupling losses of power in the signal. The above-noted reference teaches the losses of this configuration to be between 15.6 to 19.0 dB, whereas the amplification gain is only 20 dB.

U.S. Pat. No. 5,838,868 issued Nov. 17, 1998 to Krol et al. teaches a semiconductor amplifier used to amplify multiplexed optical signals in waveguides, such as optical fibres. The semiconductor material for such amplifiers is located outside of the fibre core, for example, between the cladding and the core. However, the semiconductor material is placed in close enough proximity to the core to allow optical signals, weakly confined in the core to interact with the semiconductor material. Pumping the semiconductor allows the signal in the core to stimulate light emissions in the same direction and in phase with the stimulating signal thereby adding gain to the signal.

Difficulties have been experienced in developing a practical embodiment. The problems arise because of the way that a fibre is formed, by drawing the fibre out from a preform. At present the semiconductor materials having the appropriate band gap and gain bandwidth to act as an amplifier do not necessarily have the appropriate physical properties to permit them to be easily co-drawn with the core out of the preform. Typically the materials with the correct drawing properties do not have the correct band gap or gain bandwidth. Because the band gap can be varied with thickness, efforts are being made to vary the band gap by precise drawing of the semiconductor to the desired predetermined thickness which yields the desired band gap. The thickness tolerances required to achieve the desired properties render such fabrication extremely difficult and prone to failure, because small variations in thickness can have a large impact on the band gap and thus performance of the amplifier. Further, due to the amplification occurring with respect to a multiplexed signal across a wide gain bandwidth, cross talk between signal components can be a problem. What is required is a device which overcomes the cross talk problems of the in line amplifier and which overcomes the inherent fabrication problems of such devices due to the need for extremely fine tolerances. It would also be desirable to reduce or eliminate the signal losses associated with coupling SOAs to waveguides, as well as avoiding the fabrication problems associated with coupling dissimilar materials together.

### SUMMARY OF THE INVENTION

The present invention provides individual amplification of signal components at the demultiplexed stage thereby eliminating any cross talk concerns; as the signals are demultiplexed prior to amplification there is no cross talk. The present invention further couples the amplifier to the signal path without creating losses through spot size conversion and alignment issues. The present invention is simple to make and can be mass produced. In a preferred form the present invention provides the elements for demultiplexing, gating and multiplexing all on the same substrate, along a signal path comprised of a generally continuous core surrounded by an appropriate cladding to form a waveguide. A thin film semiconductor is used as a gate material and is located outside of the signal component carrying core but close enough to the core to interact with the optical signal component contained therein. The semiconductor can be made any suitable thickness and made from any material having an appropriate band gap and gain bandwidth. Because there is no need to draw the semiconductor material of the present invention, but only deposit it onto a compatible substrate or cladding material, the drawing properties of the material are irrelevant. Further, because the coupling losses are reduced, a significant signal gain can be achieved for signal components which pass through the gate of the present invention.

According to one aspect of the present invention there is provided a gate for an optical signal, said gate comprising:

a waveguide which can be coupled to a source of optical signals, wherein the waveguide comprises a cladding surrounding a core;

a thin film semiconductor being sized, shaped and positioned outside of said core such that an optical signal passing along said core interacts with said thin film semiconductor; and

a source of power to stimulate said thin film semiconductor, said power source being switchable between being on and off;

wherein said optical signal is attenuated by interacting with said semiconductor film when said source of power is off and said optical signal is amplified by interacting with said semiconductor film when said source of power is on.

According to another aspect of the present invention there is provided a packaged optical signal wavelength selector comprising:

a substrate for carrying optical signal devices, said optical signal devices defining a signal path on said substrate, wherein said signal path can be coupled to a source of optical signals;

an optical signal multiplexer/demultiplexer in said signal path whereby signal components can be separated from a multiplexed signal;

a plurality of gates, one for each of said demultiplexed signal components, each of said gates comprising;

a waveguide comprised of a cladding surrounding a core;

a thin film semiconductor being sized, shaped and positioned outside of said core such that an optical signal passing along said core interacts with said thin film semiconductor; and

a source of power to stimulate said thin film semiconductor, said power source being switchable between being on and off;

wherein each of said optical signal components is individually attenuated or amplified by interacting with said semiconductor film depending upon whether the source of power is on or off for each gate.

According to a further aspect of the present invention there is provided a method of forming an optical signal gate comprising the steps of:

a) forming a substrate;

b) forming a cladding on said substrate;

c) forming at least a core for a planar optical signal multiplexer/demultiplexer on said cladding, said planar multiplexer/demultiplexer including a single multiplexed signal core at one end and a plurality of demultiplexed signal cores in a gate region at the other end;

d) depositing a gate material adjacent to each of the plurality of cores in said gate region; and

e) depositing a cladding around all of said cores and said gate material to form waveguides.

### BRIEF DESCRIPTION OF THE DRAWINGS

Reference will now be made, by way of example only, to the following drawings which show preferred embodiments of the present invention and in which:

FIG. 1 shows a plan view of one embodiment of a packaged optical signal wavelength selector according to the present invention;

FIG. 2 is a cross section along lines 2-2 of FIG. 1;

FIG. 3 is a side view along lines 3-3 of FIG. 2;

FIG. 4 is a graph of the transmission of a signal compared to pump power for a typical material; and

FIG. 5 shows the variance of band gap wavelength with thickness of film for a typical semiconductor material.

### DETAILED DESCRIPTION OF THE PREFERRED EMBODIMENTS

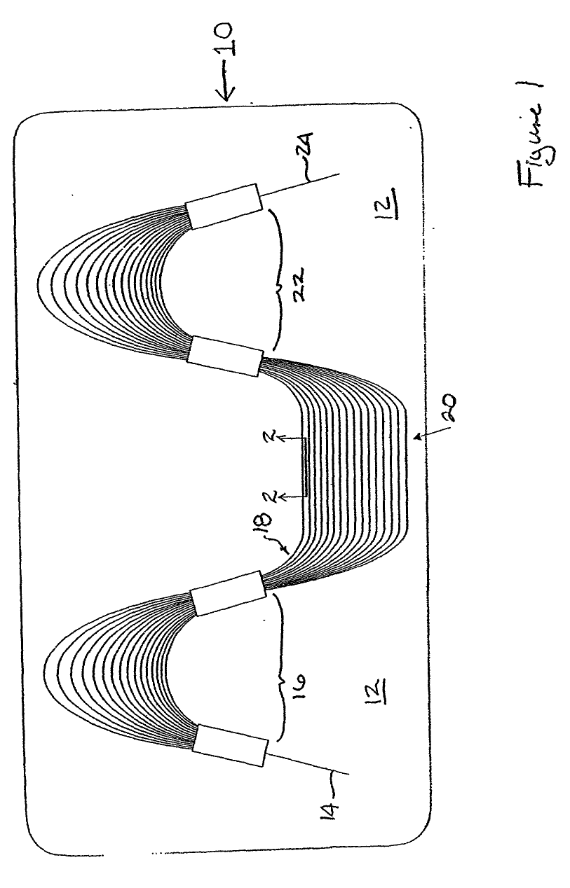

FIG. 1 shows a packaged optical signal wavelength selector generally at 10 according to the present invention. The selector 10 includes a substrate 12, onto which a number of optical devices are mounted. The substrate 12 may be made from any conventional material such as silicon, and the waveguide, namely the cladding and core can be made from, for example, glass, an amorphous solid, typically made mostly of silica and which may transmit light. As will be understood by those skilled in the art, other suitable material such as semiconductors are also available. In this disclosure the term light includes that portion of the electromagnetic radiation spectrum that is useful in and used for signal communication including the visible spectrum, the near infra red and near ultra violet portions of the spectrum. Of particular interest at present are the C and L bands.

FIG. 1 shows a first optical signal path 14, followed by a first demultiplexing/multiplexing element, which by way of example is an arrayed wave guide (AWG) 16. Then there are a plurality of signal paths 18 which traverse a gate forming region 20. Then there is a second demultiplexing/ multiplexing element such as AWG 22 and a second optical signal path 24. The AWGs 16 and 22 permit a multiplexed signal comprised of a plurality of signal components passing in one direction to be separated into individual signal components (demultiplexed) and in the opposite direction to be multiplexed together into a single multiplexed signal. It will be understood therefore that the device of the present invention is bidirectional and can deal with signals travelling in either direction through the device. Each signal path 18 corresponds to a single signal component. Thus, for a 40 signal component system, there would be 40 separate paths 18. For a 160 signal component system there would need to be 160 separate paths 18.

Other forms of multiplexer/demultiplexer 16,22 can also be used, but AWGs are preferred because they are inherently planar waveguide devices. AWGs are typically fabricated from silica on a silicon substrate, but may also be made from other suitable materials such as semiconductors for example, silicon on silicon, indium phosphide or the like. The AWGs 16 and 22 are conventional and as their operation will be understood by those skilled in the art, they are not described in any more detail.

The optical signal path through the device of the present invention is continuous through a homogeneous core material. There are no boundaries or interfaces between dissimilar materials as in the prior art which require spot sized converters or the like. Thus, a continuous signal path is provided from one side of the device to the other which apart from the typical losses arising from passing the signal through the AWGs is otherwise lossless. This is explained in more detail below.

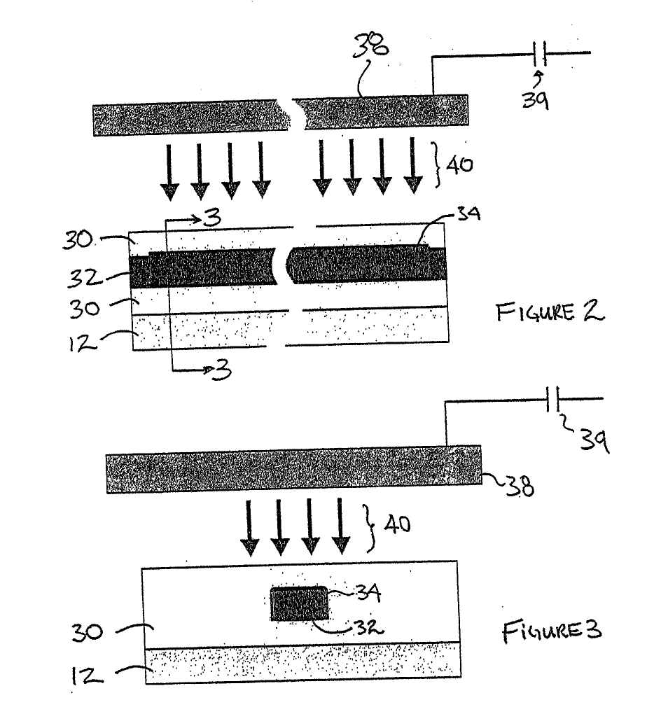

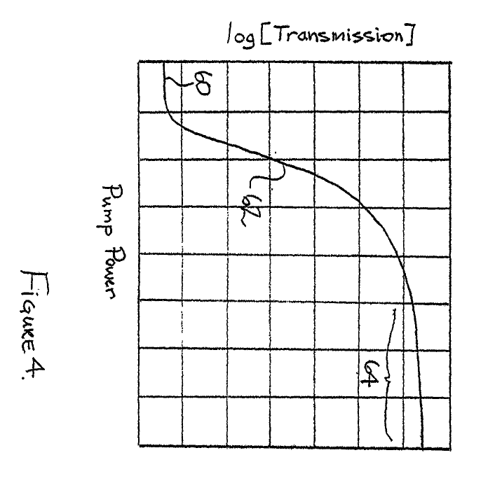

FIG. 3 shows a cross sectional view of one of the signal paths 18 in the gate forming region 20 of FIG. 1. As shown, the substrate 12 is generally continuous and has had a cladding 30 deposited or otherwise mounted thereto. Contained within the cladding is a single waveguide core 32 and mounted outside of the core 32 is a thin film of gate material 34. It will be understood that although only one of the individual waveguides 18 crossing the gate forming region 20 is being shown, there will be as many of such waveguides 18 as there are signal components being demultiplexed from the signal by the AWGs 16 and 22. Although different signal components travel down each of the signal paths, since each of the signal paths 18 are substantially identical in structure, only one is being shown in any detail and the description of this one applies equally to the other signal paths not shown in detail. FIG. 2 shows a side view along part of the signal path 18 of FIG. 1. Also shown in FIGS. 2 and 3 is a source of power 38, which may be energized through a switch 39 to produce pump energy 40. As shown the pump energy 40 is optical energy, such as produced by an LED.

The preferred material for the substrate 12 is one that is easy to use in the fabrication of packaged optical devices, such as silicon. Most preferably the substrate 12 will have a surface and be made from a material to which the cladding material may be easily attached using known techniques. The cladding is also preferably a light transmissive material and is selected to have an index of refraction which is slightly less than that of the waveguide core. In this way the core/cladding interface will act to guide the signal components travelling along the core according to conventional techniques for single mode devices.

As will be understood by those skilled in the art even though the signal is contained in the mode field, the mode field extends beyond the core and into the cladding. In a single mode waveguide, such as are common for the telecommunications industry, the further from the core the weaker the mode field and thus the weaker the signal is. According to one preferred aspect of the present invention, a semiconductor or gate material is located between the core and the cladding. In this way the semiconductor material can still be outside of the core and yet interact with the mode field and the signal. Further, by being located close to, or at the surface of the core, the interaction between the signal and the gate material is maximized. According to the present invention the gate material is in the form of a thin film 34 adjacent to the core 32 and positioned in a location relative to the core 32 to permit the signal components passing down the core 32 to interact with the gate material 34. In this sense, interact means that the signal component is either attenuated or amplified by the presence of the gate material 34. Thus, while close proximity to the core 32 is preferred, it is not essential, provided sufficient attenuation and amplification can be obtained through a signal to gate material interaction to achieve the desired gating function.

The gate material 34 may be any suitable material which has the desired effect of being switchable between at least two states, namely, an amplifying state and an absorbing state, as explained in more detail below. The most preferred form of the gate material is a thin film semiconductor, such as, for example, InGaAs. The semiconductor material may be a binary, ternary or quaternary material. Reasonable results may be obtained with one or more of the following: CdS, CdTe, CdSSe, GaAs, GaSb, InP, InAs, InSb, InGaAs, InAlGaAs, PbS, PbCdS, PbSiS, HgCdTe, InGaAsP, AlInP, AlGaAs, AlInAs, AlGaSb, AlInSb, GaInP, GaInSb, GaAsP, GaAsSb, InPAs, and InAsSb.

According to one aspect of the present invention, the interaction between a known signal light and the semiconductor material can be predetermined through the choice of semiconductor material, the position of the material relative to the core and through the thickness of the semiconductor film. The preferred semiconductor material will be switchable between states in which it can absorb incident signal light (act as a closed gate) and amplify the signal (act at least as an open gate and even boost the signal). The details of this can now be described.

The choice of semiconductor gate material according to the present invention is related to the specific characteristics of the signal light being gated. For example, to successfully act as a closed gate, the signal must be absorbed enough so that it no longer can be manipulated downstream from the gate. To be absorbed, the photon energy of the signal light must be higher than the band gap energy of the semiconductor gate material. That is, the wavelength of the signal light must be less than the wavelength which corresponds to the band gap emission. If the photon energy of the signal light is lower than the band gap energy (corresponding to higher wavelengths) the semiconductor material is simply devoid of any energy transitions which are capable of strongly interacting with the signal light. This makes the semiconductor material transparent to the signal light. To the extent the semiconductor material is transparent, it is less able to absorb any light, and thus unable to act as a closed gate.

In the event the photon energy of the signal light is indeed higher than the band gap energy, then an incident photon can be absorbed through an interband transition, resulting in the excitation of an electron from the valence band to the conduction band, generating an electron-hole pair. A subsequent recombination of such an electron-hole pair will result in a spontaneous emission. In an unpumped gate material having the requisite properties very few electron-hole pairs are present and substantially all of the signal light energy is absorbed in, creating electron-hole pairs. As the pairs spontaneously recombine, light energy is emitted, but such light is spatially isotropic, rather than being emitted in a direction along the path of the waveguide as is the case for stimulated emissions. Further, a portion of emitted light is typically shifted to a lower energy level, which can take it outside of the communication band. The net effect of these two events is to reduce, or attenuate the power of the signal light. Thus, the present invention comprehends that the semiconductor or gate material is sized, shaped and positioned relative to the signal carrying core, and is selected from a material which is light absorbing (when unpumped) having regard to the photon energy of the signal light to attenuate the signal light sufficiently to deselect the same from the network. Thus, for deselection full attenuation of the signal is not required, merely sufficient signal attenuation to inhibit practical signal manipulation after the gate.

If, on the other hand the semiconductor material of the present invention is pumped, either electrically or most preferably optically by exposure to a source of electromagnetic radiation, then there will be many electron-hole pairs present in the material. In such case, the signal component interacting with the pumped material will cause the material to emit stimulated light. The stimulated emission will be in phase with and in the same direction as the stimulating signal component and thus the stimulated emissions amplify the signal component resulting in signal gain. Thus, according to the present invention the same material can act as an absorber or closed gate when not pumped and an amplifier or open gate when pumped.

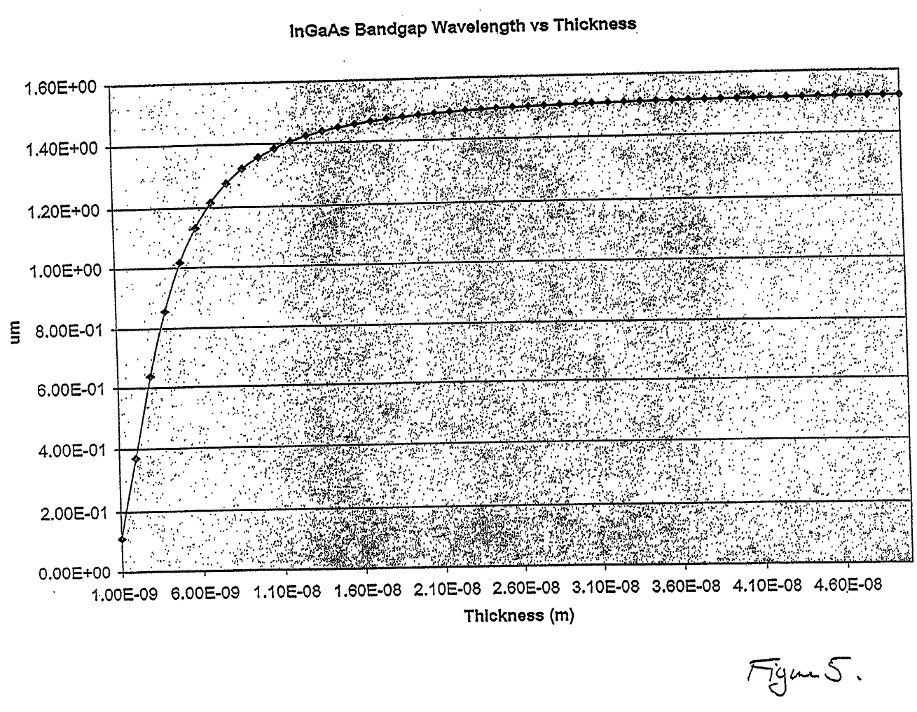

The difference between absorption and amplification is illustrated in the graph of FIG. 4. In this graph the amount of signal light transmitted is shown logarithmically on the y-axis, while the amount of pump power used is shown on the x-axis. As can be seen, for low pump power the amount of signal that can be transmitted is very low shown at 60. As the pump power increases, there is a relatively sharp rise at 62 in the amount of signal transmitted until the amount of signal transmitted plateaus at 64. It is preferred, according to the present invention, to select a semiconductor material which has a change between the pumped and the unpumped states of at least 30 dB, and more preferably 40 to 50 dB. A further desired characteristic of the thin film material is that the pump power causes a significant increase (or amplification) in signal transmission but also, is as low as possible to reduce energy consumption. It can now be appreciated that the present invention comprehends individual signal component switching control on demand because, if the thin layer is pumped, the signal component is amplified and if it is not pumped, the signal component is attenuated enough to be deselected from further signal processing or manipulation.

Further, the gate material must have the property that the power of the signal by itself is sufficiently low so that when not pumped by an external pump the gate material strongly absorbs and does not start to approach transparency. Thus the gate material and film thickness are selected such that for the range of powers of the signal components passing through the gate, the gate material continues to exhibit a good contrast or extinction ratio.

It will be appreciated that absorption mechanisms other than interband transitions exist such as intraband, phonon excitation and impurity-to-band. Most often these mechanisms do not result in light emission by recombination, except for some instances in the case of impurity-to-band transitions. Thus, these other mechanisms, while good at attenuating or blocking the signal light do not in turn amplify when pumping is turned on. Thus, they are believed unsuitable for the present invention. The most preferred mechanism is to use interband transitions in direct band gap materials.

The present invention also comprehends that the source of power might be electrical. In this case the substrate and core each need to be one of a p or n-doped material and the cladding the other. Thus, a junction is formed at the semiconductor gate material and the electrical power can then be converted into energy to create electron-hole pairs, when the current is applied. An example of a suitable material for the substrate or cladding where an electrical power source is used is indium phosphide. At present this material is difficult to work with and thus, while possible to use, it is believed that optical pumping is preferred. The present invention comprehends electrical power sources which may become more desirable as the materials improve, or as new gate materials are developed.

A number of factors affect the performance of the gate according to the present invention. For example, FIG. 5 shows the relationship between band gap wavelength vs. thickness of film. The communications band is centered around the wavelength of 1550 nm. Thus it can be seen that as long as the thin film of gate material is thicker than about 2.5×10⁻⁸ metres thick, a stable band gap wavelength will be attained. Thus, in manufacturing, as long as the minimum thickness is achieved, the appropriate band gap wavelength can be obtained.

A gate material that has an appropriate band gap energy along the flat part of the curve is preferred because then small differences in thickness, that might arise during manufacturing, will have little effect on the band gap energy. If the functional characteristics of the device are not significantly affected by changes in thickness, then less care need be taken in manufacturing and the devices can be made less expensively. However, it may be that a suitable material requires a thickness corresponding to the sloped portion of the curve, where small changes in thickness can affect band gap energy. Because the present invention involves the simple deposition of the gate material onto a core, it will be possible to carefully control the thickness of the gate material to very fine tolerances by known techniques.

Another factor affected by the thickness of the gate material is the amount of amplification provided. The amount of amplification is related to the amount of electron-hole pairs that the stimulating signal encounters. The density of electron-hole pairs in a pumped semiconductor material is much higher than, for example, doped fibre amplifiers. Thus, less volume of material is required to achieve the same amount of amplification. The amplification factor is a function of the film volume, which in turn is related to the width, length and thickness of the film. It will be noted that the film cannot be made too thick, because then it will start to draw the mode field outside of the core and into the semiconductor material. This can result in an amplified signal component, but one that is then lost because at the end of the overlapping semiconductor material, the signal component is not coupled back into the core. Thus, in selecting the thickness of the gate material, amplification is optimized without distorting the mode field so much so as to cause a significant loss of signal from the core.

Another factor affected by the thickness of the film is the ability to pump the semiconductor material. The preferred pump of the present invention is a light emitting diode (LED) which is an inexpensive yet efficient source of electromagnetic radiation. LEDs are semiconductor diodes that emit incoherent light by means of spontaneous emission, and can be packaged together in the form of an array. Thus, one diode can be provided for each signal path 18, permitting the electromagnetic pump energy to be quickly turned on and off to open and close the gate respectively. Further, the incoherent light emitted from the diode spreads so as to be able to pump both the sides and the top of a core, provided the width of the emitter is greater than the width of the core. Alternatively, a focussed source, such as a laser could be used, in which case more of the gate material would have to be along one face of the core, or, some reflecting structures would be needed to illuminate the other faces. Since as stated above the real consideration is to tune the desired amplification by means of the choice of volume of gate material interacting with the signal, various shapes of the gate material on the core are comprehended. The present invention further comprehends varying the pump power to also tune the gain or amplification provided. For an optically or electromagnetically pumped material the cladding will need to be sufficiently transparent to permit the pump light to sufficiently stimulate the material to create the necessary level of electron-hole pairs. Further the use of optical or electromagnetic pumping will also impose some constraints on the thickness of the semiconductor material, in that if it is too thick, it may no longer be readily pumpable.

Fabrication of a device according to the present invention can now be understood. The first issue is to choose the right semiconductor or gate material. InGaAs is believed to provide reasonable results. Then, a substrate can be formed, and one or both AWGs may be formed on the substrate. They are formed by first depositing a cladding material and then forming the cores. At this stage, the waveguide cores in the gate region of the AWG are left exposed. Then, the gate material can be added around one or more sides of the core to a predetermined thickness and length to achieve a desired gain as noted above. Next, the cladding is further built up around and over the thin film gate material and the core.

As will be appreciated by those skilled in the art, the fabrication of devices with thin films can be somewhat difficult. Thus, to preserve the properties of the thin film, during for example an annealing step, it may be desirable to place an anti-diffusion layer between the cladding and the gate material.

It will be understood that a number of configurations are comprehended by the present invention. For example, the thin film may be located on the sides as well as the top of the core. Further, the material may be formed as thin discrete strips associated with each signal path, or may be made as a continuous film across the gate region. If the latter is the case, pump power control is required to prevent the film from being stimulated other than adjacent to the individual signal paths. Otherwise opening one gate might have the undesirable effect of opening the adjacent gates. However, this should not be a problem if the gates are sufficiently spaced apart to prevent unwanted opening of adjacent gates.

As can be seen the thin film 34 extends along the signal path for a certain length. While this length can vary, it will be understood that the length will be a function of the desired amount of absorption and amplification. The longer the length, for a given film thickness, if unpumped the greater the absorption and if pumped the greater the amplification.

Most preferably the semiconductor material of the present invention is amenable to optical excitation so it may be pumped by an LED for example in this case, if a photon with more than the band gap energy strikes the semiconductor, it can raise an electron from the valence band to the conduction band, creating an electron and a hole. Conversely, a photon from the signal component with less than the band gap energy is simply absorbed by the material if the material is not being pumped.

The operation of the present invention can be now be understood. A multiplexed signal arrives at one end, and is demultiplexed as it passes into the device through either AWG 16 or 22. As a result of demultiplexing each individual signal component (whether there are 40, 160 or any other number) will be passed through an individual waveguide core in the gate region 20. The signal components will then interact with the gate material, and either be absorbed (thus blocking the signal) or amplified (thus, boosting and pumping the signal along). By electronically switching the power source on and off, by, in the preferred embodiment, energizing or de-energizing individual LEDs in the associated LED array rapid switching can occur between the absorption and amplification states. Extinction ratios of up to 40 dB or more are attainable, at switching speeds as low as nanoseconds. Further, the insertion losses are reduced to minimum.

It will be understood by those skilled in the art that while reference has been made to various preferred embodiments of the invention in the foregoing description, various alterations and modifications are possible without detracting from the broad scope of the appended claims. Some of these have been discussed above and others will be apparent to those skilled in the art. For example, while reference is made to using LED for pump power, other forms of pump power could also be used. LEDs are convenient because they can be designed in prepackaged arrays and are rapidly responsive to being turned on and off.

The embodiments of the invention in which an exclusive property or privilege is claimed are defined as follows:

1. A gate for an optical signal, said gate comprising:
a waveguide which can be coupled to a source of optical signals, wherein
the waveguide comprises a cladding surrounding a core;
a gate material being sized, shaped and positioned outside of said core such that an optical signal passing along said core interacts with said gate material; and
a source of power to stimulate said gate material, said power source being switchable between being on and off;
wherein said optical signal is attenuated by interacting with said gate material when said source of power is off and said optical signal is amplified by interacting with said gate material when said source of power is on.

2. A gate as claimed in claim 1 wherein said gate material is a thin film semiconductor.

3. A gate as claimed in claim 2 wherein said optical signal has a predetermined wavelength band and said thin film semiconductor has a thickness which provides a band gap energy suitable to amplify said optical signal in said predetermined wavelength band.

4. A gate as claimed in claim 2 wherein said optical signal has a predetermined wavelength band and said thin film semiconductor is formed from a semiconductor material having a band gap energy suitable for amplifying said predetermined wavelength band.

5. A gate as claimed in claim 2 wherein said optical signal has a predetermined wavelength band and said thin film semiconductor is formed from a semiconductor material having gain bandwidth which covers said wavelength band.

6. A gate as claimed in claim 2 further including an anti-diffusion layer extending between the thin film semiconductor and said waveguide to prevent said thin film semiconductor from diffusing into said waveguide during fabrication.

7. A gate as claimed in claim 2 further including an anti-diffusion layer extending between the thin film semiconductor and said cladding to prevent said thin film semiconductor from diffusing into said cladding during fabrication.

8. A gate as claimed in claim 6 wherein said optical signal travelling along said core is sufficiently weakly contained to permit interaction with said thin film semiconductor.

9. A gate as claimed in claim 2 wherein said optical signal passing through said waveguide has a typical power and said thin film semiconductor is sufficiently absorptive to prevent said thin film semiconductor from becoming transparent to said signal at said typical power.

10. A gate as claimed in claim 2 wherein said semiconductor material causes an amount of attenuation sufficient to deselect said optical signal interacting with said thin film semiconductor when said power is off.

11. A gate as claimed in claim 2 wherein said thin film semiconductor is one or more of a binary, ternary or quaternary compound.

12. A gate as claimed in claim 2 wherein said thin film semiconductor has a lattice spacing compatible with said cladding and said core to facilitate crystal growth.

13. A gate as claimed in claim 2 wherein said thin film semiconductor is selected from the group of CdS, CdTe, CdSSe, GaAs, GaSb, InP, InAs, InSb, InGaAs, InAlGaAs, PbS, PbCdS, PbSiS, HgCdTe, InGaAsP, AlInP, AlGaAs, AlInAs, AlGaSb, AlInSb, GaInP, GaInSb, GaAsP, GaAsSb, InPAS, and InAsSb.

14. A gate as claimed in claim 1 wherein said source of power is light.

15. A packaged optical signal wavelength selector comprising:
a substrate for carrying optical signal devices, said optical signal devices defining a signal path on said substrate, wherein said signal path can be coupled to a source of optical signals;
an optical signal multiplexer/demultiplexer in said signal path whereby signal components can be separated from a single path multiplexed signal into a plurality of paths each having a single demultiplexed signal component;
a plurality of gates, one for each of said demultiplexed signal components, each of said gates comprising;
a waveguide comprised of a cladding surrounding a core;
a thin film semiconductor being sized, shaped and positioned outside of said core such that an optical signal passing along said core interacts with said thin film semiconductor; and
a source of power to stimulate said thin film semiconductor, said power source being switchable between being on and off;
wherein each of said optical signal components is individually attenuated or amplified by interacting with said semiconductor film depending upon whether the source of power is on or off for each gate.

16. A packaged optical signal wavelength selector as claimed in claim 15 wherein each of said signal components has a predetermined wavelength band and said thin film semiconductor has a thickness which provides a band gap energy suitable to amplify said signal components in each of said predetermined wavelength bands.

17. A packaged optical signal wavelength selector as claimed in claim 15 wherein each of said signal components has a predetermined wavelength band and said thin film semiconductor is formed from a semiconductor material having a band gap energy suitable for amplifying each of said predetermined wavelength bands.

18. A packaged optical signal wavelength selector as claimed in claim 15 wherein each of said signal components has a predetermined wavelength band and said thin film semiconductor is formed from a semiconductor material having an amplification band which covers each of said wavelength bands.

19. A packaged optical signal wavelength selector as claimed in claim 15 wherein said thin film semiconductor is in the form of a plurality of strips, one adjacent to each of said demultiplexed signal paths.

20. A packaged optical signal wavelength selector as claimed in claim 15 further including an anti-diffusion layer extending between the thin film semiconductor and said waveguide core to prevent said thin film semiconductor from diffusing into said waveguide core during fabrication.

21. A packaged optical signal wavelength selector as claimed in claim 15 further including an anti-diffusion layer extending between the thin film semiconductor and said cladding to prevent said thin film semiconductor from diffusing into said cladding during fabrication.

22. A packaged optical signal wavelength selector as claimed in claim 15 wherein each of said signal components travelling along said core is sufficiently weakly contained to permit interaction between said signal and said thin film semiconductor.

23. A packaged optical signal wavelength selector as claimed in claim 15 wherein said signal components passing through said waveguide have a typical power and said thin film semiconductor is sufficiently absorptive to prevent said thin film semiconductor from becoming transparent to said signal at said typical power.

24. A packaged optical signal wavelength selector as claimed in claim 15 wherein said thin film semiconductor causes an amount of attenuation sufficient to deselect said signal component interacting with said thin film semiconductor when said power is off.

25. A packaged optical signal wavelength selector as claimed in claim 15 wherein said thin film semiconductor is one or more of a binary, ternary or quaternary compound.

26. A packaged optical signal wavelength selector as claimed in claim 15 wherein said thin film semiconductor has a lattice spacing compatible with said cladding and said core to facilitate crystal growth.

27. A packaged optical signal wavelength selector as claimed in claim 15 wherein said thin film semiconductor is selected from the group of CdS, CdTe, CdSSe, GaAs, GaSb, InP, InAs, InSb, InGaAs, InAlGaAs, PbS, PbCdS, PbSiS, HgCdTe, InGaAsP, AlInP, AlGaAs, AlInAs, AlGaSb, AlInSb, GaInP, GaInSb, GaAsP, GaAsSb, InPAS, and InAsSb.

28. A packaged optical signal wavelength selector as claimed in claim 15 wherein said source of power is light.

29. A method of forming an optical signal gate comprising the steps of:
a) forming a substrate;
b) forming a cladding on said substrate;
c) forming at least a core for a planar optical signal multiplexer/de-multiplexer on said cladding, said planar multiplexer/demultiplexer including a single multiplexed signal core at one end and a plurality of demultiplexed signal cores in a gate region at the other end;
d) depositing a gate material adjacent to each of the plurality of cores in said gate region; and
e) depositing a cladding around all of said cores and said gate material to form waveguides.

30. A method of forming an optical signal gate as claimed in claim 29 wherein said step of depositing a gate material includes selecting a gate material having a band gap energy lower than a photon energy of a signal component to be carried in said core.

31. A method of forming an optical signal gate as claimed in claim 29 wherein said step of depositing said gate material comprises depositing said gate material onto said plurality of cores in said gate region.

32. A method of forming an optical signal gate as claimed in claim 29 wherein said step of depositing said gate material includes depositing said gate material in thin strips adjacent to each core.

33. A method of forming an optical signal gate as claimed in claim 29 further including the step of attaching a pump source to said substrate.

34. A method of forming an optical signal gate as claimed in claim 33 wherein said pump source comprises an LED array.

35. A method of forming an optical signal gate as claimed in claim 29 wherein said substrate, said core, said gate material and said cladding all comprise materials having a compatible lattice spacing.

36. A method of forming an optical signal gate as claimed in claim 29 further including the step of forming a planar optical signal multiplexer/demultiplexer on both sides of said gate region.

37. A method of forming an optical signal gate as claimed in claim 29 further including forming said cladding and said substrate from one of a p-doped or an n-doped material and supplying a source of electrical energy to pump said gate material.
